(19) United States
(12) Patent Application Publication
(10) Pub. No.: US 2017/0263627 A1
(43) Pub. Date: Sep. 14, 2017

(54) SEMICONDUCTOR MEMORY DEVICE AND METHOD FOR MANUFACTURING THE SAME

(71) Applicant: KABUSHIKI KAISHA TOSHIBA, Tokyo (JP)

(72) Inventors: Takashi FURUHASHI, Kuwana Mie (JP); Masayuki TANAKA, Yokkaichi Mie (JP); Shinji MORI, Yokkaichi Mie (JP)

(21) Appl. No.: 15/253,969

(22) Filed: Sep. 1, 2016

(30) Foreign Application Priority Data
Mar. 14, 2016 (JP) 2016-050103

(51) Int. Cl. H01L 27/115; H01L 21/28; H01L 29/51

(52) U.S. Cl. CPC H01L 27/11582; H01L 29/517; H01L 21/28282; H01L 29/513

(57) ABSTRACT

A semiconductor memory device includes a semiconductor layer, a stacked body on the semiconductor layer, the stacked body including a first insulating layer and an electrode layer, a channel layer within and extending through the stacked body and electrically connected to the semiconductor layer, a second insulating layer between the channel layer and the electrode layer, a charge storage layer between the second insulating layer and the electrode layer, and a third insulating layer between the charge storage layer and the electrode layer. The third insulating layer includes an insulating film on a side of the charge storage layer and a first dielectric layer on a side of the electrode layer. The first dielectric layer includes a first material, a second material, and oxygen. The first material has a dielectric constant higher than a dielectric constant of aluminum oxide when the first material is converted into an oxide, and an oxide of the second material has a dielectric constant lower than the dielectric constant of the oxide of the first material.

### CROSS-REFERENCE TO RELATED APPLICATION

This application is based upon and claims the benefit of priority from Japanese Patent Application No. 2016-050103, filed Mar. 14, 2016, the entire contents of which are incorporated herein by reference.

### FIELD

Embodiments described herein relate generally to a semiconductor memory device and a method for manufacturing the same.

### BACKGROUND

Each memory cell of a semiconductor memory, such as a NAND-type electrically erasable programmable read-only memory (EEPROM), is provided with a charge blocking layer between a charge storage layer and en electrode (word line). If the dielectric constant of the charge blocking layer is too low, charges may tunnel back from the electrode to the charge storage layer during data erasing. In this case, time needed for data erasing may increase. On the other hand, if the dielectric constant of the charge blocking layer is too high, a large electrical stress may be applied to a tunnel film during data writing and erasing. This electrical stress may cause the tunnel film to deteriorate.

### DESCRIPTION OF THE DRAWINGS

FIG. 1 is a cross-sectional view illustrating an example of a configuration of a NAND-type EEPROM according to a first embodiment.

FIG. 2 is a plan view illustrating an example of an arrangement of memory holes and slits.

FIG. 3 is a cross-sectional view illustrating an example of a configuration of a charge blocking layer and surrounding layers.

FIGS. 4A and 4B are cross-sectional views illustrating an example of a method for manufacturing a memory according to the first embodiment.

FIGS. 5A and 5B are cross-sectional views illustrating the method for manufacturing the memory, following FIGS. 4A and 4B.

FIGS. 6A and 6B are cross-sectional views illustrating the method for manufacturing the memory, following FIGS. 5A and 5B.

FIGS. 7A and 7B are cross-sectional views illustrating the method for manufacturing the memory, following FIGS. 6A and 6B.

FIG. 8 is a cross-sectional view illustrating the method for manufacturing the memory, following FIGS. 7A and 7B.

FIG. 9 is a cross-sectional view illustrating an example of a configuration of a charge blocking layer and surrounding layers of a memory according to a second embodiment.

FIG. 10 is a cross-sectional view illustrating an example of a configuration of a charge blocking layer and surrounding layers of a memory according to a third embodiment.

### DETAILED DESCRIPTION

According to an embodiment, there is provided a semiconductor memory device including a semiconductor layer, a stacked body on the semiconductor layer, the stacked body including a first insulating layer and an electrode layer, a channel layer within and extending through the stacked body and electrically connected to the semiconductor layer, a second insulating layer between the channel layer and the electrode layer, a charge storage layer between the second insulating layer and the electrode layer, and a third insulating layer between the charge storage layer and the electrode layer. The third insulating layer includes an insulating film on a side of the charge storage layer and a first dielectric layer on a side of the electrode layer. The first dielectric layer includes a first material, a second material, and oxygen, the first material having a dielectric constant higher than a dielectric constant of aluminum oxide when the first material is converted into an oxide, and an oxide of the second material having a dielectric constant lower than the dielectric constant of the oxide of the first material.

Hereinafter, embodiments will be described with reference to the drawings. The embodiments described herein should not be construed to limit the disclosure. In the following embodiments, upward and downward directions of a semiconductor layer indicate relative directions defined in a case where the surface on which a semiconductor element is provided is supposed to be the upper side, and may be different from upward and downward directions defined according to gravitational forces.

### First Embodiment

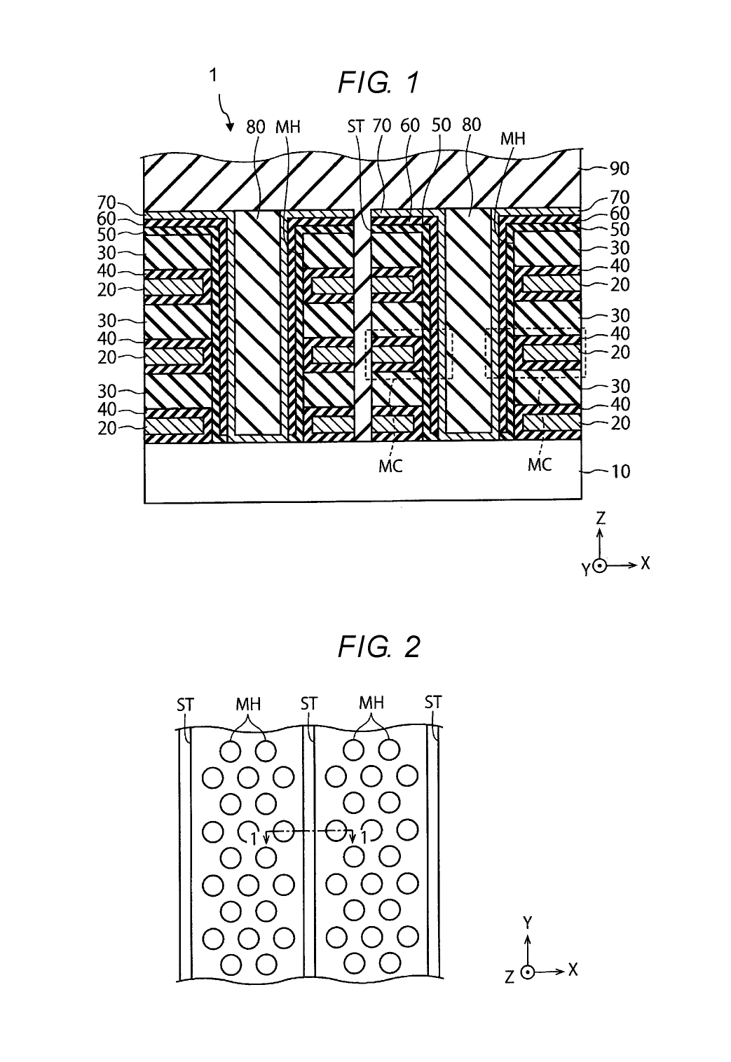

FIG. 1 is a cross-sectional view illustrating an example of a configuration of a NAND-type EEPROM 1 (hereinafter referred to also as a “memory 1”) according to a first embodiment. The memory 1 can be, for example, a stacked type memory in which memory cells are three-dimensionally arranged.

The memory 1 includes a semiconductor layer 10, an electrode layer 20, an interlayer insulating layer 30, a charge blocking layer 40, a charge storage layer 50, a tunnel insulating layer 60, a channel layer 70, a core insulating layer 80, and an interlayer insulating layer 90.

The semiconductor layer 10 can be, for example, a semiconductor substrate, such as a silicon substrate. Alternatively, the semiconductor layer 10 can be formed as a silicon on insulator (SOI) layer.

A plurality of electrode layers 20 are stacked in layers above the semiconductor layer 10 in the Z-direction, which is approximately perpendicular to the surface of the semiconductor layer 10. Furthermore, the electrode layer 20 extends in the Y-direction, which is perpendicular to a plane of the drawing sheet of FIG. 1, above the surface of the semiconductor layer 10, and is a conductive layer functioning as a word line and a control electrode for each memory cell. Accordingly, the plurality of electrode layers 20, which are arranged adjacent to one another in the Z-direction (in the stacking direction of the electrode layers 20), are electrically separated from one another by the interlayer insulating layer 30 and the charge blocking layer 40. The electrode layer 20 contains, for example, a conductive metal, such as tungsten or titanium nitride (TiN).

The interlayer insulating layers 30, each of which serves as a first insulating (dielectric) layer, are also stacked in layers above the semiconductor layer 10 in the Z-direction. Each interlayer insulating layer 30 is provided between the electrode layers 20 that are arranged adjacent to each other in the Z-direction. Thus, the electrode layer 20 and the interlayer insulating layer 30 configure a stacked body in which the electrode layers 20 and the interlayer insulating layers 30 are alternately stacked one by one above the surface of the semiconductor layer 10 in the Z-direction. The interlayer insulating layer 30 contains, for example, an insulating material, such as silicon oxide film.

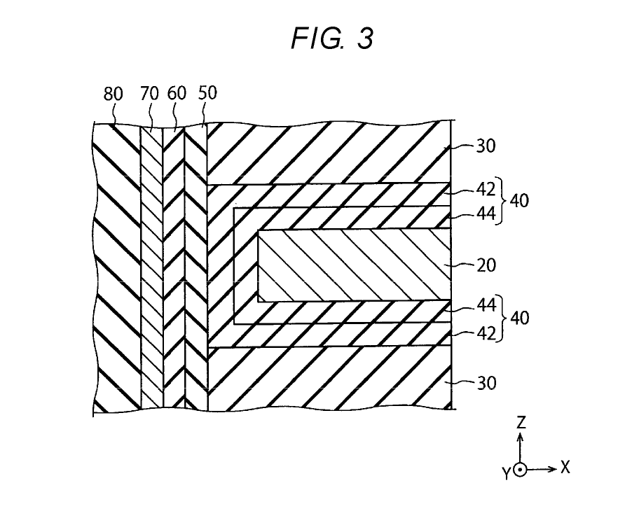

The charge blocking layers 40, each of which serves as a third insulating (dielectric) layer, are provided between the electrode layer 20 and the interlayer insulating layer 30 and between the charge storage layer 50 and the electrode layer 20. Thus, in the present embodiment, the charge blocking layers 40 are provided on three surfaces (one side surface, an upper surface, and a lower surface) of the electrode layer 20. The charge blocking layer 40 has a function to prevent tunneling of charge between the charge storage layer 50 and the electrode layer 20. For example, during data writing, the charge blocking layer 40 prevents electrons from flowing from the channel layer 70 to the electrode layer 20 while passing through the charge storage layer 50. During data erasing, the charge blocking layer 40 prevents electrons from flowing from the electrode layer 20 to the channel layer 70 while passing through the charge storage layer 50 (back tunneling). Details of the configuration of the charge blocking layer 40 are further described below with reference to FIG. 3.

The stacked body, which includes the electrode layer 20 and the interlayer insulating layer 30, has a memory hole MH formed therein, which extends from the top surface to the bottom surface of the stacked body along the Z-direction. Thus, the upper end of the memory hole MH is located at the upper surface of the interlayer insulating layer 30 that is the uppermost layer of the stacked body, and the lower end of the memory hole MH is located at the surface of the semiconductor layer 10, so that the memory hole MH extends along the Z-direction, which is the stacking direction of the stacked body. The charge storage layer 50, the tunnel insulating layer 60, and the channel layer 70 are provided on the inner surface of the memory hole MH. Moreover, the core insulating layer 80 is provided in the memory hole MH and fills the memory hole MH.

The charge storage layer 50 is provided on the side surface of the interlayer insulating layer 30 and the side surface of the charge blocking layer 40 in the inner surface of the memory hole MH. The charge storage layer 50 is provided between the tunnel insulating layer 60 and the electrode layer 20, and faces the side surface of the electrode layer 20 via the charge blocking layer 40. A portion of the charge storage layer 50 facing one electrode layer 20 corresponds to the charge storage layer 50 of one memory cell MC. The charge storage layer 50 contains, for example, a semiconductor material, such as polysilicon, a high-dielectric material, such as SiN, HfSiO, and HfSiON, or a high-dielectric material containing a metal. The charge storage layer 50 of each memory cell MC receives charge (electron) from the channel layer 70 via the tunnel insulating layer 60 during data writing, and emits charge to the channel layer 70 via the tunnel insulating layer 60 during data erasing. This enables the memory cell MC to store data, in the form of electric charges, in the charge storage layer 50.

The tunnel insulating layer 60, which serves as a second insulating (dielectric) layer, is provided on the charge storage layer 50 in the inner surface of the memory hole MH. Thus, the tunnel insulating layer 60 is provided between the channel layer 70 and the electrode layer 20, and faces the side surface of the electrode layer 20 via the charge blocking layer 40 and the charge storage layer 50. The tunnel insulating layer 60 contains, for example, an insulating material, such as silicon oxide film.

The channel layer 70 is provided on the tunnel insulating layer 60 in the inner surface of the memory hole MH. Thus, the channel layer 70 is provided between the core insulating layer 80 and the electrode layer 20, and faces the side surface of the electrode layer 20 via the tunnel insulating layer 60, the charge blocking layer 40, and the charge storage layer 50. The channel layer 70 is electrically connected to the semiconductor layer 10 at the bottom portion of the memory hole MH. Moreover, although not illustrated, the channel layer 70 is connected to a bit line via a contact plug. With this, the channel layer 70 is electrically connected between the bit line and the semiconductor layer 10 via the memory hole MH. The channel layer 70 contains, for example, a conductive material, such as amorphous silicon, polysilicon, and metal. A charge (electron), when receiving an electric field (positive voltage) from the electrode layer 20, flows out of the channel layer 70, tunnels through the tunnel insulating layer 60, and is then stored in the charge storage layer 50. Alternatively, a charge, when receiving an electric field (negative voltage) from the electrode layer 20, flows out of the charge storage layer 50, tunnels through the tunnel insulating layer 60, and is then emitted to the channel layer 70.

The core insulating layer 80 is provided on the channel layer 70 in the memory hole MH. The core insulating layer 80 is provided in such a way as to fill in the memory hole MH.

The interlayer insulating layer 90 is further provided on the core insulating layer 80 and the channel layer 70. The interlayer insulating layer 90 is provided with a contact plug (not illustrated) or the like that connects the channel layer 70 and the bit line.

The slit ST is used to form the electrode layer 20 and the charge blocking layer 40. Moreover, the interlayer insulating layer 90 is provided in the slit ST, thus electrically separating adjacent memory cells MC provided at both sides of the slit ST from each other.

FIG. 2 is a plan view illustrating an example of an arrangement of the memory holes MH and the slits ST. FIG. 1 corresponds to a cross-section taken along line 1-1 in FIG. 2. The memory holes MH, each of which is approximately circular in a planar layout, are arrayed in a matrix arrangement between the adjacent slits ST. The slit ST is provided to be elongated in the Y-direction as in the extending direction of the electrode layer 20 (word line) in a planar layout and extends in a direction approximately perpendicular to the X-direction, which is the extending direction of the bit line (not illustrated). The interlayer insulating layer 90 is provided in the slit ST. Accordingly, the slit ST electrically separates the electrode layers 20 located at both sides thereof from each other. On the other hand, the memory holes MH located between the adjacent slits ST share the electrode layer 20 (word line).

FIG. 3 is a cross-sectional view illustrating an example of a configuration of the charge blocking layer 40 and its surroundings. The charge blocking layer 40 is a stacked film including an insulating film 42 and a first dielectric layer 44. The insulating film 42 contains a material having a lower dielectric constant than the first dielectric layer 44, and is, for example, a silicon oxide film. Hereinafter, the insulating film 42 is referred to also as a “silicon oxide film 42”. The silicon oxide film 42 is provided closer to the charge storage layer 50 than the first dielectric layer 44, and is provided between the first dielectric layer 44 and the charge storage layer 50 and between the first dielectric layer 44 and the interlayer insulating layer 30. On the other hand, the first dielectric layer 44 is provided closer to the electrode layer 20 than the silicon oxide film 42, and is provided between the silicon oxide film 42 and the electrode layer 20.

The first dielectric layer 44 is a layer including a first material and a second material. The first or second material, or both, may contain oxygen, and the first dielectric layer may also contain oxygen in a non-binding state. The first material is a high-dielectric material having a dielectric constant higher than a dielectric constant of aluminum oxide (AlO) when the first material is converted into an oxide. The first material contains, for example, at least one of zirconium (Zr), hafnium (Hf), lanthanum (La), and yttrium (Y). These materials become, when converted into oxides, an oxide of zirconium (ZrO), an oxide of hafnium (HfO), an oxide of lanthanum (LaO), and an oxide of yttrium (YO), which have a dielectric constant higher than a dielectric constant of aluminum oxide. The second material has a dielectric constant lower than a dielectric constant of the oxide of the first material, and is added as an additive to the first material. Accordingly, for descriptive purposes, the second material is referred to also as an additive. The additive contains, for example, a material including at least one of silicon (Si), aluminum (Al), yttrium (Y), lanthanum (La), and hafnium (Hf). Each of the first material and the additive can include two or more of the above-mentioned materials.

Furthermore, for example, in a case where yttrium, lanthanum, or hafnium is used for the first material, a material having a dielectric constant lower than a dielectric constant of the first material is used for the additive.

The first material and the additive in the first dielectric layer 44 can be mixed in a non-binding state, or can be bound into a compound. Furthermore, oxygen in the first dielectric layer 44 can be bound to at least one of the first material and the additive into a compound, or can be mixed with the at least one of the first material and the additive in a non-binding state. For example, oxygen can be bound to the first material and the first material can be present as an oxide in the first dielectric layer 44. In this case, the first dielectric layer 44 can be a layer in which a layer of the oxide of the first material and a layer of the additive are alternately stacked one by one. Moreover, for example, in a case where zirconium is used for the first material and silicon is used for the additive, the first dielectric layer 44 can be, as a result, a layer in which an oxide of zirconium and an oxide of silicon are stacked in layers.

The dielectric constant of the oxide of the first material is higher than the dielectric constant of an oxide of aluminum. However, the dielectric constant of the additive is lower than the dielectric constant of the oxide of the first material. Accordingly, as a result, the dielectric constant of the first dielectric layer 44 is higher than dielectric constant of an oxide of aluminum, but is lowered to some extent by the introduction of the additive. For example, in a case where zirconium is used for the first material, the dielectric constant of an oxide of zirconium (ZrO) is higher than dielectric constant of an oxide of aluminum. Furthermore, in a case where silicon is used for the additive, since the dielectric constant of an oxide of silicon is lower than dielectric constant of an oxide of zirconium (ZrO), the dielectric constant of the first dielectric layer 44 has a dielectric constant between the dielectric constant of an oxide of zirconium (ZrO) and the dielectric constant of an oxide of silicon, which is a dielectric constant somewhat lower than the dielectric constant of an oxide of zirconium (ZrO). Moreover, the dielectric constant of the first dielectric layer depends on the additive amount of the additive. Additionally, this is not limited in a case where the crystalline phase is changed due to elemental addition. For example, in a case where silicon or the like is added to an oxide of hafnium (HfO), due to the transition to a high-dielectric constant crystalline phase, the dielectric constant rises when the addition proceeds up to a certain concentration, and, as the additive amount is further increased, the dielectric constant decreases again.

In this way, making the dielectric constant of the first dielectric layer 44 higher than the dielectric constant of an oxide of aluminum enables preventing charges from tunneling between the electrode layer 20 and the channel layer 70. Accordingly, relatively raising the dielectric constant of the first dielectric layer 44 enables preventing charge (electron) from tunneling back from the electrode layer 20 to the charge storage layer 50 in a case where a negative voltage is applied to the electrode layer 20 during data erasing. Preventing the back tunneling reduces charge flowing from the electrode layer 20 into the charge storage layer 50 during data erasing, so that a data erasing time can be minimized. Thus, data erasing characteristics can be improved.

On the other hand, if the dielectric constant of the first dielectric layer 44 is too high, an electric field emanating from the electrode layer 20 is strongly applied to the tunnel insulating layer 60, so that the tunnel insulating layer 60 may deteriorate. The deterioration of the tunnel insulating layer 60 influences data retention characteristics of a memory, thus adversely affecting reliability. Therefore, in the first dielectric layer 44 according to the present embodiment, the additive is introduced into the oxide of the first material so as to somewhat lower the dielectric constant of the oxide of the first material. This enables reducing an electric field applied to the tunnel insulating layer 60 and preventing any deterioration of the tunnel insulating layer 60.

Furthermore, in the present embodiment, the silicon oxide film 42 of the charge blocking layer 40 is provided at the side closer to the charge storage layer 50, and the first dielectric layer 44 thereof is provided at the side closer to the electrode layer 20. With this, the first dielectric layer 44, which has dielectric constant higher than dielectric constant of an oxide of aluminum, is located away from the tunnel insulating layer 60 by the thickness of the silicon oxide film 42. Thus, the silicon oxide film 42 intervening between the first dielectric layer 44 and the charge storage layer 50 reduces an electric field emanating from the electrode layer 20 and applied to the tunnel insulating layer 60. This prevents any deterioration of the tunnel insulating layer 60. In this way, the charge blocking layer 40 according to the present embodiment is capable of preventing tunneling of charge between the electrode layer 20 and the charge storage layer 50 and also preventing any deterioration of the tunnel insulating layer 60.

Moreover, in the present embodiment, the dielectric constant of the first dielectric layer 44 is decreased not by providing a thick low-dielectric film but by adding the additive. Accordingly, without an increase of the film thickness of the entire charge blocking layer 40, the dielectric constant of the first dielectric layer 44 is lowered to some extent. This enables the first dielectric layer 44 according to the present embodiment to prevent an increase in size of the memory cell MC.

Next, a method for manufacturing the memory 1 according to the present embodiment is described.

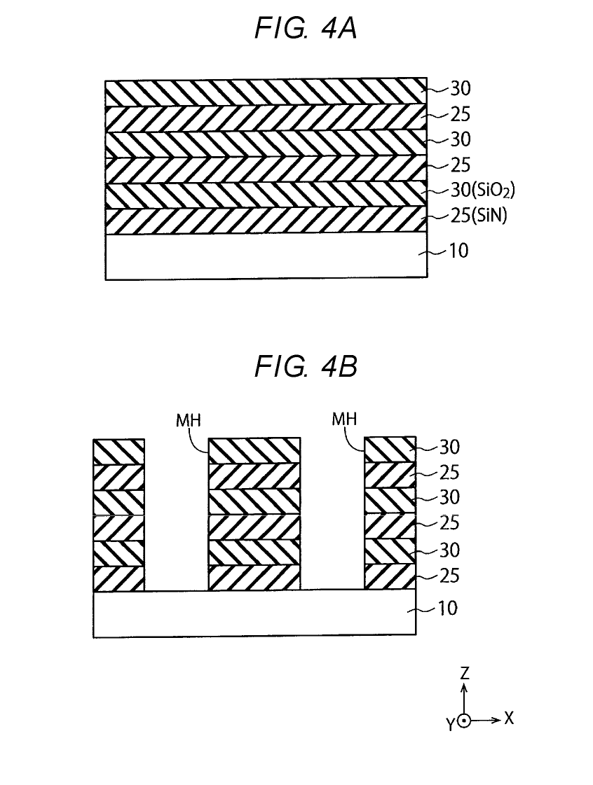

FIGS. 4A and 4B to FIG. 8 are cross-sectional views illustrating an example of a method for manufacturing the memory 1 according to the first embodiment.

First, as illustrated in FIG. 4A, the manufacturing method stacks a sacrificial layer 25 and the interlayer insulating layer 30 alternately and iteratively on the semiconductor layer 10, thus forming a multi-layer stacked body. The sacrificial layer 25 is made from, for example, silicon nitride film. The interlayer insulating layer 30, which serves as a first insulating layer, is made from, for example, silicon oxide film. The sacrificial layer 25 and the interlayer insulating layer 30 are formed using a chemical vapor deposition (CVD) method or an atomic layer deposition (ALD) method.

Next, as illustrated in FIG. 4B, the manufacturing method forms the memory holes MH in the stacked body using a reactive ion etching (RIE) method. Each memory hole MH is formed along the Z-direction, which is the stacking direction of the stacked body, in such a way as to lead from the upper surface of the interlayer insulating layer 30 of the uppermost layer in the stacked body to the semiconductor layer 10 (in such a way as to penetrate through the stacked body). With this, the side surfaces of the sacrificial layer 25 and the interlayer insulating layer 30 become exposed on the inner side surface of the memory hole MH. The memory holes MH, each of which is approximately circular in a planar layout, are arrayed in a matrix arrangement, as described above with reference to FIG. 2.

Next, the manufacturing method forms the charge storage layer 50 on the inner surface of the memory hole MH using an ALD method or a CVD method. The charge storage layer 50 is formed on the side surfaces of the sacrificial layer 25 and the interlayer insulating layer 30 exposed in the memory hole MH. The charge storage layer 50 is made from, for example, silicon nitride film.

Next, the manufacturing method further forms the tunnel insulating layer 60 on the inner surface of the memory hole MH using the ALD method or the CVD method. The tunnel insulating layer 60, which serves as a second insulating layer, is formed on the charge storage layer 50. Thus, the tunnel insulating layer 60 is formed on the inner surface of the memory hole MH via the charge storage layer 50. The tunnel insulating layer 60 is made from, for example, silicon oxide film.

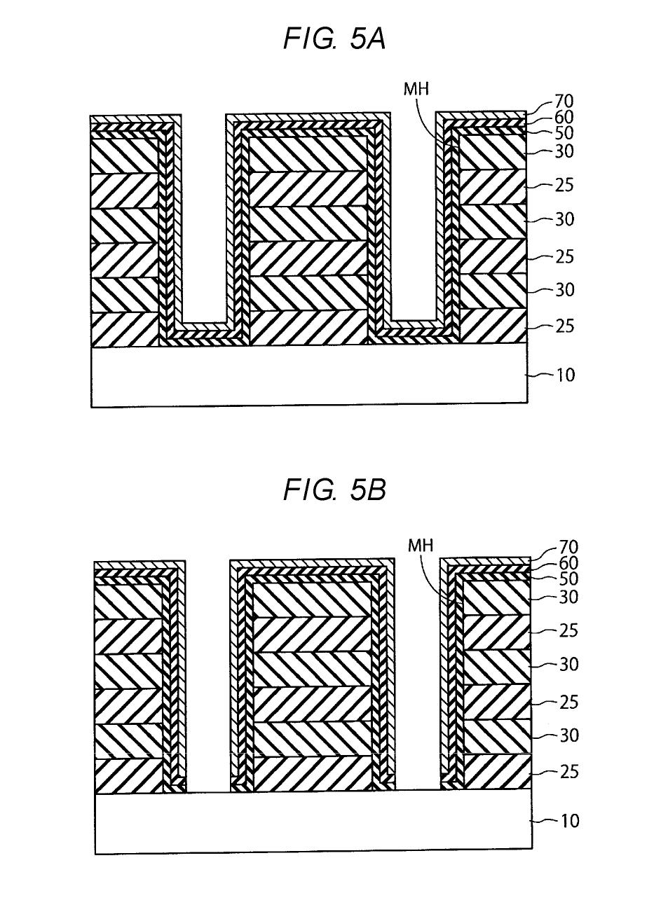

Next, the manufacturing method further forms the channel layer 70 on the inner surface of the memory hole MH using the ALD method or the CVD method. The channel layer 70 is formed on the tunnel insulating layer 60. Thus, the channel layer 70 is formed on the inner surface of the memory hole MH via the charge storage layer 50 and the tunnel insulating layer 60. The channel layer 70 contains, for example, amorphous silicon. With this, a structure illustrated in FIG. 5A is obtained.

Next, as illustrated in FIG. 5B, the manufacturing method removes the channel layer 70, the tunnel insulating layer 60, and the charge storage layer 50 formed at the bottom portion of the memory hole MH using a lithography technology and the RIE method. At this time, the surface layer of the semiconductor layer 10 can be somewhat removed. In other words, the semiconductor layer 10 may be overetched. With this, the surface of the semiconductor layer 10 becomes exposed while the channel layer 70, the tunnel insulating layer 60, and the charge storage layer 50 are allowed to remain on the inner side surface of the memory hole MH.

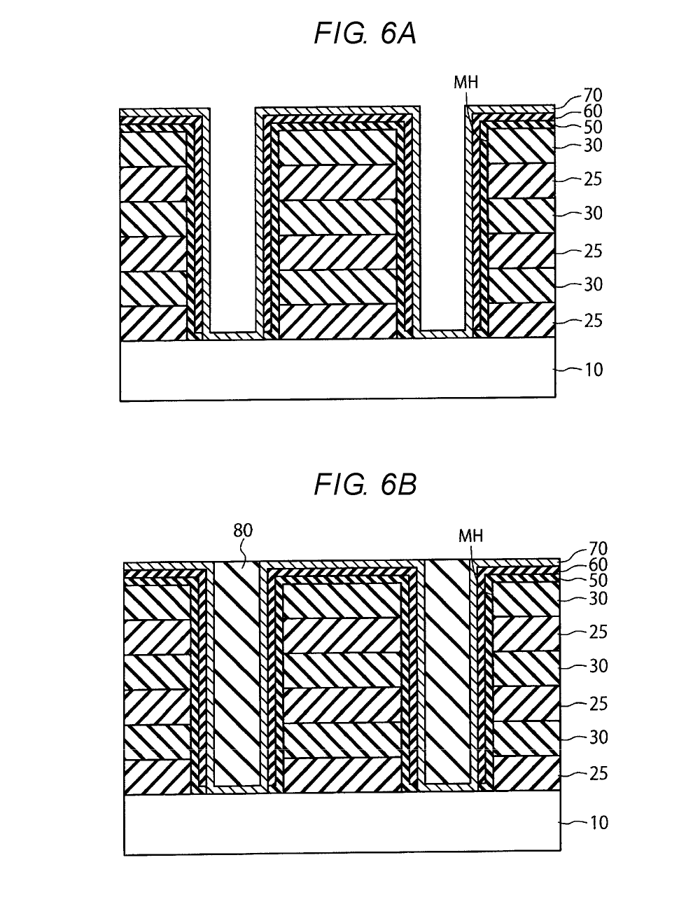

Next, as illustrated in FIG. 6A, the manufacturing method re-forms the channel layer 70 on the inner surface of the memory hole MH using the ALD method or the CVD method. With this, the channel layer 70 is electrically connected to the semiconductor layer 10 at the bottom portion of the memory hole MH and is electrically connected up to the upper surface of the stacked body via the side surface of the memory hole MH.

Next, the manufacturing method utilizes heat treatment to crystallize the channel layer 70 into polysilicon.

Next, the manufacturing method forms the core insulating layer 80 in the memory hole MH using the CVD method. The core insulating layer 80 is formed on the channel layer 70 in the memory hole MH. The core insulating layer 80 is made from, for example, silicon oxide film. The core insulating layer 80 is planarized using a chemical mechanical polishing (CMP) method or the like. With this, a structure illustrated in FIG. 6B is obtained.

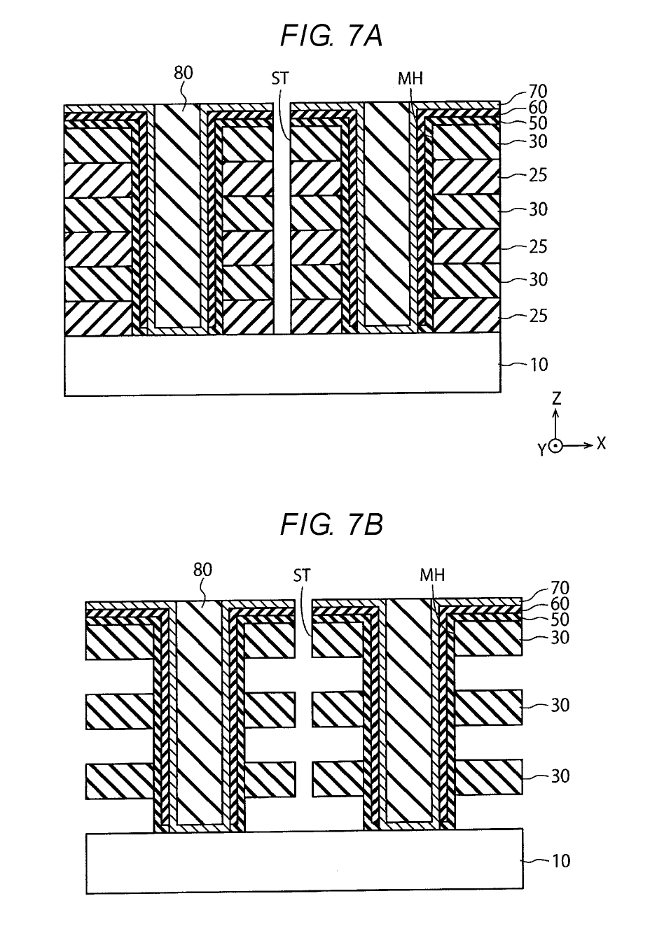

Next, as illustrated in FIG. 7A, the manufacturing method forms the slit ST in the stacked body, which includes the sacrificial layer 25 and the interlayer insulating layer 30, using the RIE method. The slit ST is formed in the sacrificial layer 25 and the interlayer insulating layer 30 between the adjacent memory holes MH so as to lead to the semiconductor layer 10. The slit ST extends in the Y-direction in a planer layout, as described above with reference to FIG. 2.

Next, the manufacturing method selectively removes the sacrificial layer 25 via the slit ST using a wet etching method. In a case where the sacrificial layer 25 contains a nitride of silicon, the manufacturing method removes the sacrificial layer 25 using a hot phosphoric acid solution. With this, a structure illustrated in FIG. 7B is obtained.

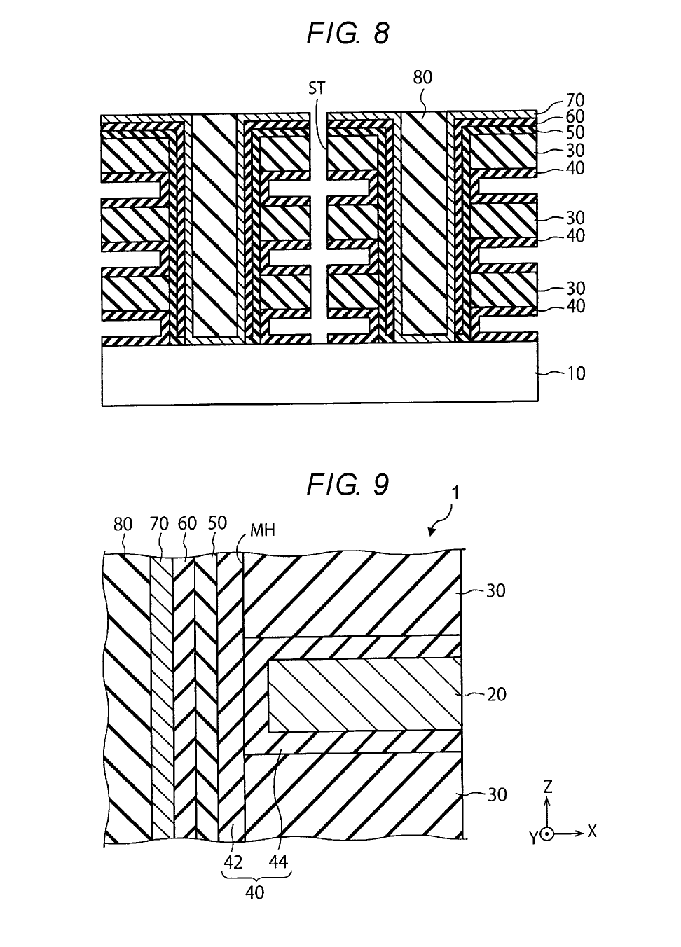

Next, as illustrated in FIG. 8, the manufacturing method forms the charge blocking layer 40 at the portions at which the sacrificial layer 25 has been removed, using the ALD method. Thus, the manufacturing method forms the charge blocking layer 40 on the opposite surfaces of the interlayer insulating layers 30 adjacent in the Z-direction and the side surface of the charge storage layer 50. The charge blocking layer 40 is a stacked film including the insulating film 42 and the first dielectric layer 44. After forming the insulating film 42 on the side surface of the charge storage layer 50 and the upper surface and lower surface of the interlayer insulating layer 30, the manufacturing method forms the first dielectric layer 44 on the insulating film 42. With this, the insulating film 42 is formed at the side closer to the charge storage layer 50, and the first dielectric layer 44 is formed at the side closer to the electrode layer 20. Furthermore, the insulating film 42 contains a material having dielectric constant lower than dielectric constant of the first dielectric layer 44, and is, for example, a silicon oxide film. Hereinafter, the insulating film 42 is referred to also as a “silicon oxide film 42”.

The first dielectric layer 44 contains a material composed by adding an additive to an oxide of the first material. The oxide of the first material is, for example, a material including at least one of an oxide of zirconium (ZrO), an oxide of hafnium (HfO), an oxide of lanthanum (LaO), and an oxide of yttrium (YO). The additive contains a material including at least one of silicon (Si), aluminum (Al), yttrium (Y), lanthanum (La), and hafnium (Hf).

In the case of forming the first dielectric layer 44 using the ALD method, the manufacturing method deposits one layer of the additive (for example, silicon) after depositing every few layers of an oxide of the first material (for example, an oxide of zirconium (ZrO)). With this, an oxide of the first material and a layer of the additive are alternately stacked one by one at a given ratio. The ratio of the additive in the first dielectric layer 44 can be, for example, obtained in a case where one layer of the additive is deposited each time four layers of an oxide of the first material are deposited. Forming the first dielectric layer 44 in this way makes the dielectric constant of the first dielectric layer 44 to be somewhat lower than the dielectric constant of an oxide of the first material. Furthermore, if the additive amount of the additive is too small, the dielectric constant of the first dielectric layer 44 cannot be lowered, so that a large stress may be applied to the tunnel insulating layer 60. On the other hand, if the additive amount of the additive is too large, it is difficult for the charge blocking layer 40 to prevent back tunneling of charge.

Moreover, the silicon oxide film 42 and the first dielectric layer 44 included in the charge blocking layer 40 can be sequentially formed using the same apparatus. This enables preventing an interfacial layer from being formed in the charge blocking layer 40, and enables forming a high-quality charge blocking layer 40.

Next, the manufacturing method forms the electrode layer 20 on the charge blocking layer 40 using the CVD method. Thus, the manufacturing method forms the electrode layer 20 via the charge blocking layer 40 on the opposite surfaces of the interlayer insulating layers 30 adjacent in the Z-direction and the side surface of the charge storage layer 50. The electrode layer 20 can be, for example, a stacked body composed of tungsten and TiN.

After that, the manufacturing method resumes to form the interlayer insulating layer 90, contact plugs, wirings, etc., so that the memory 1 illustrated in FIG. 1 is completed.

In this way, according to the present embodiment, the silicon oxide film 42 is formed at the side closer to the charge storage layer 50, and the first dielectric layer 44 is formed at the side closer to the electrode layer 20. Moreover, the dielectric constant of the first dielectric layer 44 is higher than the dielectric constant of an oxide of aluminum, and is somewhat lower than the dielectric constant of an oxide of the first material. This enables preventing charge (electron) from tunneling back from the electrode layer 20 to the charge storage layer 50 during data erasing, and enables reducing an electric field applied to the tunnel insulating layer 60 and preventing any deterioration of the tunnel insulating layer 60.

### Second Embodiment

FIG. 9 is a cross-sectional view illustrating an example of a configuration of a charge blocking layer 40 and its surroundings of a memory 1 according to a second embodiment. The charge blocking layer 40 according to the second embodiment is similar to the charge blocking layer 40 employed in the first embodiment in that the charge blocking layer 40 is a stacked film including the silicon oxide film 42 and the first dielectric layer 44. Furthermore, between the side surface of the electrode layer 20 and the charge storage layer 50, the silicon oxide film 42 is provided at the side closer to the charge storage layer 50 and the first dielectric layer 44 is provided at the side closer to the electrode layer 20.

However, in the second embodiment, the silicon oxide film 42 is provided on the inner surface of the memory hole MH, and is thus provided on the side surface of the first dielectric layer 44 and the side surface of the interlayer insulating layer 30. The silicon oxide film 42 is not provided between the first dielectric layer 44 and the interlayer insulating layer 30. On the other hand, the first dielectric layer 44 is provided between the charge storage layer 50 and the electrode layer 20 and between the interlayer insulating layer 30 and the electrode layer 20.

The manufacturing method for the memory 1 according to the second embodiment, after forming the memory holes MH illustrated in FIG. 4B, forms the silicon oxide film 42 in the memory hole MH using the CVD method or the ALD method. After that, as described above with reference to FIG. 5A, the manufacturing method forms the charge storage layer 50, the tunnel insulating layer 60, and the channel layer 70 in the memory hole MH. Thus, the manufacturing method forms the silicon oxide film 42 on the inner surface of the memory hole MH after forming the memory hole MH and before forming the charge storage layer 50.

Moreover, after removing the sacrificial layer 25 as illustrated in FIG. 7B, the manufacturing method forms the first dielectric layer 44 without forming the silicon oxide film 42. The other processes in the second embodiment can be similar to those in the first embodiment. This enables forming the memory 1 including the charge blocking layer 40 illustrated in FIG. 9.

According to the second embodiment, the silicon oxide film 42 included in the charge blocking layer 40 does not surround the electrode layer 20 but lines the inner surface of the memory hole MH. With this, the thickness and width of the electrode layer 20 are increased, so that the resistance value of the electrode layer 20 can be lower. Thus, the word line resistance can be lower.

On the other hand, the first dielectric layer 44 is provided at the surroundings of the electrode layer 20 as with the first dielectric layer 44 employed in the first embodiment. Accordingly, a plurality of first dielectric layers 44 adjacent in the Z-direction are separated from one another for each electrode layer 20. Therefore, charge in the charge storage layer 50 can be prevented from moving to another memory cell MC adjacent in the Z-direction via the first dielectric layer 44. Thus, charge in a memory cell MC can be retained in that memory cell MC. With this, data in another memory cell can be prevented from being disturbed. Furthermore, the second embodiment can also attain the advantageous effect of the first embodiment.

### Third Embodiment

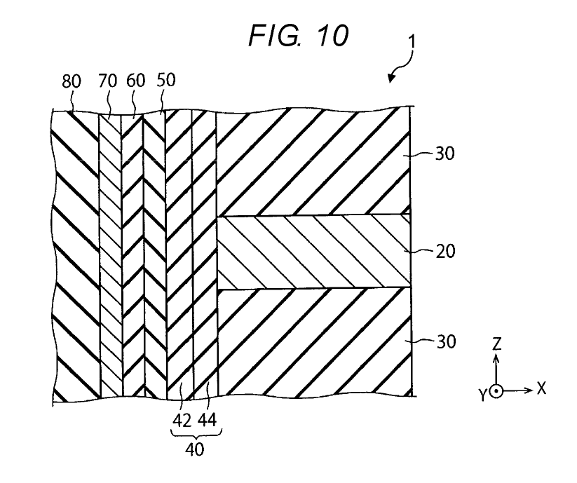

FIG. 10 is a cross-sectional view illustrating an example of a configuration of a charge blocking layer 40 and its surroundings of a memory 1 according to a third embodiment. The charge blocking layer 40 according to the third embodiment is similar to the charge blocking layer 40 employed in the first embodiment in that the charge blocking layer 40 is a stacked film including the silicon oxide film 42 and the first dielectric layer 44. Furthermore, between the side surface of the electrode layer 20 and the charge storage layer 50, the silicon oxide film 42 is provided at the side closer to the charge storage layer 50 and the first dielectric layer 44 is provided at the side closer to the electrode layer 20.

However, in the third embodiment, both the silicon oxide film 42 and the first dielectric layer 44 are provided on the inner surface of the memory hole MH, and are thus provided on the side surface of the electrode layer 20 and the side surface of the interlayer insulating layer 30. The silicon oxide film 42 and the first dielectric layer 44 are not provided between the electrode layer 20 and the interlayer insulating layer 30.

The manufacturing method for the memory 1 according to the third embodiment, after forming the memory holes MH illustrated in FIG. 4B, forms the first dielectric layer 44 and the silicon oxide film 42 in the memory hole MH using the ALD method. After that, as described above with reference to FIG. 5A, the manufacturing method forms the charge storage layer 50, the tunnel insulating layer 60, and the channel layer 70 in the memory hole MH. Thus, the manufacturing method forms the first dielectric layer 44 and the silicon oxide film 42 on the inner surface of the memory hole MH after forming the memory hole MH and before forming the charge storage layer 50.

Moreover, after removing the sacrificial layer 25 as illustrated in FIG. 7B, the manufacturing method forms the electrode layer 20 without forming the silicon oxide film 42 and the first dielectric layer 44. The other processes in the third embodiment can be similar to those in the first embodiment. This enables forming the memory 1 including the charge blocking layer 40 illustrated in FIG. 10.

According to the third embodiment, the charge blocking layer 40 does not surround the electrode layer 20 but lines the inner surface of the memory hole MH. With this, the thickness and width of the electrode layer 20 are further increased, so that the resistance value of the electrode layer 20 can be further made lower. Thus, the word line resistance can be further decreased.

On the other hand, since the first dielectric layer 44 is also provided on the inner surface of the memory hole MH, a plurality of first dielectric layers 44 adjacent in the Z-direction are not separated from one another for each electrode layer 20. Accordingly, there is a concern that charge in the charge storage layer 50 may move to another adjacent memory cell MC in the Z-direction via the first dielectric layer 44. However, in a case where disturbance to another memory cell is very small, it is inconsequential. Rather, the third embodiment has an advantage to make the resistance value of the electrode layer 20 very low. Furthermore, the third embodiment can also attain the advantageous effect of the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device comprising:
a semiconductor layer;
a stacked body on the semiconductor layer, the stacked body including a first insulating layer and an electrode layer;
a channel layer within and extending through the stacked body and electrically connected to the semiconductor layer;
a second insulating layer between the channel layer and the electrode layer;
a charge storage layer between the second insulating layer and the electrode layer; and
a third insulating layer between the charge storage layer and the electrode layer, the third insulating layer including an insulating film on a side of the charge storage layer and a first dielectric layer on a side of the electrode layer,
wherein the first dielectric layer includes a first material and a second material, the first material having a dielectric constant higher than a dielectric constant of aluminum oxide when the first material is converted into an oxide, and an oxide of the second material having a dielectric constant lower than the dielectric constant of the oxide of the first material, wherein the first material contains oxygen, the second material contains oxygen, or the first dielectric layer contains oxygen in a non-binding state.

2. The semiconductor memory device according to claim 1, wherein the first material includes at least one of zirconium (Zr), hafnium (Hf), lanthanum (La), and yttrium (Y).

3. The semiconductor memory device according to claim 2, wherein the second material includes at least one of silicon (Si), aluminum (Al), yttrium (Y), lanthanum (La), and hafnium (Hf).

4. The semiconductor memory device according to claim 3, wherein the third insulating layer is between the charge storage layer and the electrode layer and between the first insulating layer and the electrode layer.

5. The semiconductor memory device according to claim 3, wherein the first dielectric layer included in the third insulating layer is between the charge storage layer and the electrode layer and between the first insulating layer and the electrode layer.

6. The semiconductor memory device according to claim 2, wherein the third insulating layer is between the charge storage layer and the electrode layer and between the first insulating layer and the electrode layer.

7. The semiconductor memory device according to claim 2, wherein the first dielectric layer included in the third insulating layer is provided between the charge storage layer and the electrode layer and between the first insulating layer and the electrode layer.

8. The semiconductor memory device according to claim 1, wherein the third insulating layer is between the charge storage layer and the electrode layer and between the first insulating layer and the electrode layer.

9. The semiconductor memory device according to claim 1, wherein the first dielectric layer included in the third insulating layer is between the charge storage layer and the electrode layer and between the first insulating layer and the electrode layer.

10. A semiconductor memory device comprising:
a semiconductor layer;
a stacked body on the semiconductor layer, the stacked body including a first insulating layer and an electrode layer;
a channel layer within and extending through the stacked body and electrically connected to the semiconductor layer;
a second insulating layer between the channel layer and the electrode layer;
a charge storage layer between the second insulating layer and the electrode layer; and
a third insulating layer between the charge storage layer and the electrode layer, the third insulating layer including an insulating film on a side of the charge storage layer and a first dielectric layer on a side of the electrode layer, wherein
the first dielectric layer includes a first material and a second material, the first material having a dielectric constant higher than a dielectric constant of aluminum oxide and a dielectric constant of the second material.

11. The semiconductor memory device according to claim 10, wherein the first material includes an oxide of at least one of zirconium (Zr), hafnium (Hf), lanthanum (La), and yttrium (Y).

12. The semiconductor memory device according to claim 11, wherein the second material includes an oxide of at least one of silicon (Si), aluminum (Al), yttrium (Y), lanthanum (La), and hafnium (Hf).

13. The semiconductor memory device according to claim 12, wherein the third insulating layer is between the charge storage layer and the electrode layer and between the first insulating layer and the electrode layer.

14. The semiconductor memory device according to claim 12, wherein the first dielectric layer included in the third insulating layer is between the charge storage layer and the electrode layer and between the first insulating layer and the electrode layer.

15. The semiconductor memory device according to claim 11, wherein the third insulating layer is between the charge storage layer and the electrode layer and between the first insulating layer and the electrode layer.

16. The semiconductor memory device according to claim 11, wherein the first dielectric layer included in the third insulating layer is provided between the charge storage layer and the electrode layer and between the first insulating layer and the electrode layer.

17. The semiconductor memory device according to claim 10, wherein the third insulating layer is between the charge storage layer and the electrode layer and between the first insulating layer and the electrode layer.

18. The semiconductor memory device according to claim 10, wherein the first dielectric layer included in the third insulating layer is between the charge storage layer and the electrode layer and between the first insulating layer and the electrode layer.

19. A method for manufacturing a semiconductor memory device, the method comprising:
stacking a first insulating layer and a sacrificial layer in layers on a semiconductor layer;
forming holes extending to the semiconductor layer, in the first insulating layer and the sacrificial layer;
forming a charge storage layer, a second insulating layer, and a channel layer on an inner surface of each of the holes;
forming slits, each of which extends to the semiconductor layer in a stacking direction, in the first insulating layer and the sacrificial layer between adjacent holes;
removing the sacrificial layer by the slits;
after removing the sacrificial layer, forming a third insulating layer, which includes an insulating film and a first dielectric layer stacked in layers, on opposite surfaces of adjacent first insulating layers in the stacking direction and a side surface of the charge storage layer, or forming the insulating film or the insulating film and the first dielectric layer of the third insulating layer on the inner surface of each of the holes after forming the holes and before forming the charge storage layer; and
forming an electrode layer between adjacent first insulating layers in the stacking direction by the third insulating layer,
wherein the first dielectric layer includes a first material, a second material, and oxygen, the first material having a dielectric constant higher than a dielectric constant of aluminum oxide when the first material is converted into an oxide, and an oxide of the second material having a dielectric constant lower than a dielectric constant of the oxide of the first material.

20. The method according to claim 19, wherein
the first material includes an oxide of at least one of zirconium (Zr), hafnium (Hf), lanthanum (La), and yttrium (Y), and
the second material includes an oxide of at least one of silicon (Si), aluminum (Al), yttrium (Y), lanthanum (La), and hafnium (Hf).
